(19) United States
(12) Patent Application Publication
(10) Pub. No.: US 2023/0384350 A1
(43) Pub. Date: Nov. 30, 2023

(54) ADJUSTABLE VOLTAGE SENSOR

(71) Applicant: 3M INNOVATIVE PROPERTIES COMPANY, St. Paul, MN (US)

(72) Inventors: Mark Gravermann, Erkelenz (DE); Gunther A. J. Stollwerck, Krefeld (DE); Jens Weichold, Erkelenz (DE); Christine B. Bund, Wuppertal (DE); Mirco Gunjaca, Nottuln (DE); Rainer Reeken, Dormagen (DE); Martin A. Milek, Oberhausen (DE); Sebastian Eggert-Richter, Wülfrath (DE); Joerg Hahn, Bad Neuenahr-Ahrweiler (DE); Michael H. Stalder, Uedem (DE); Christian Weinmann, Alsdorf (DE); Holger J. Kurzhals, Krefeld (DE); Christopher R. Wilson, Austin, TX (US)

(21) Appl. No.: 18/321,241

(22) Filed: May 22, 2023

Related U.S. Application Data
(60) Provisional application No. 63/365,516, filed on May 31, 2022.

(51) Int. Cl. G01R 15/06; G01R 19/00

(52) U.S. Cl. CPC G01R 15/06; G01R 19/0084

(57) ABSTRACT

A voltage sensor for sensing an AC voltage of a HV/MV power conductor comprises a capacitive voltage divider for sensing the AC voltage having one or more high-voltage capacitors electrically connected in series with each other and a low-voltage portion comprising one or more low-voltage capacitors electrically connected with each other between the high-voltage portion and electrical ground. The voltage divider also comprises a signal contact, electrically arranged between the high-voltage portion and the low-voltage portion, for providing a signal voltage indicative of the AC voltage. The low-voltage portion further comprises a plurality of electrically actuated adjustable impedance elements configured to adjust the common overall impedance of the low-voltage portion towards a desired impedance. Each electrically actuated adjustable impedance element comprises one or more associated adjustment capacitors and at least one electrically actuatable element, wherein each electrically actuatable element is associated with and electrically connected to one or more of the adjustment capacitors and wherein each electrically actuatable element is configured to achieve one of a connected state and a disconnected state. In the connected state, an associated adjustment capacitor is electrically connected in parallel to at least one of the one or more low-voltage capacitors. In the disconnected state, the associated adjustment capacitor is electrically disconnected from the low-voltage capacitor(s).

### FIELD OF THE INVENTION

The present disclosure relates to AC voltage sensors for high or medium voltage power conductors in power networks and national grids, in particular to voltage sensors comprising a voltage divider. It also relates to methods of adjusting an impedance in such voltage dividers.

### RELATED ART

Power network operators utilize voltage sensors to determine the voltage of power conductors in their networks. With decentralized energy production, knowing the state of the network is indispensable for its proper operation and maintenance.

A common type of voltage sensors for AC voltages uses voltage dividers which have a high-voltage portion and a low-voltage portion which are serially connected between the high voltage of the power conductor and electrical ground. A contact between the high-voltage and the low-voltage portion provides a divided voltage which is proportional to the voltage of the power conductor and varies with it. The divided voltage (or “signal voltage”) is measured and processed to determine the voltage of the power conductor. The proportionality factor between the voltage of the power conductor Vin and the signal voltage Vout is often referred to as the “dividing ratio” T, wherein Vout=Vin/T, and T depends on the ratio of the overall impedance of the high-voltage portion and the overall impedance of the low-voltage portion.

In order to evaluate the signal voltage independently from individual characteristics of the voltage divider, network operators often specify the dividing ratio precisely. However, the impedances of the components of the high-voltage portion and of the low-voltage portion are only specified to a certain accuracy, and their production tolerances are not negligible, so that the overall respective impedances of the high-voltage and low-voltage portions are predictable only within a certain corridor. Once assembled, the voltage divider may turn out to have a dividing ratio that is outside the accuracy specification of the network operator.

In WO 2021/059078 A1, an Adjustable Voltage Sensor is Described that Includes a Plurality of Switches Used to Selectively Adjust the Impedance of a Low Voltage Portion of the Voltage Divider.

### SUMMARY OF THE INVENTION

The current disclosure relates to voltage sensors for use with MV or HV power distribution networks. In such networks, electrical power is distributed via HV/MV cables, transformers, switchgears, substations etc. with currents of hundreds of amperes and voltages of tens of kilovolts. The term “medium voltage” or “MV” as used herein refers to an AC voltage in the range of 1 kV to 72 kV, whereas the term “high voltage” or “HV” refers to an AC voltage of more than 72 kV.

Traditionally, in high voltage (HV) and medium voltage (MV) power networks the dividing ratio of voltage dividers in AC voltage sensors was determined after assembly of the sensor and taken into account by adjusting downstream sensing circuitry (often referred to as an RTU) to the dividing ratio of the particular sensor before this sensing circuitry determined the voltage of the power conductor from the signal voltage output of the sensor. However, providing HV/MV voltage dividing sensors that have a given, consistent and predetermined dividing ratio may make the sensing circuitry simpler, because it does not need to cope with sensors having a—possibly wide—range of dividing ratios. Also, providing consistent sensors with predetermined dividing ratio facilitates exchange of one sensor for another sensor without having to adjust the sensing circuitry.

The present disclosure attempts to address these needs.

In a first aspect of the invention, a voltage sensor for sensing an AC voltage of a HV/MV power conductor comprises a capacitive voltage divider for sensing the AC voltage. The voltage divider comprises a high-voltage portion comprising one or more high-voltage capacitors electrically connected in series with each other and a low-voltage portion comprising one or more low-voltage capacitors electrically connected with each other between the high-voltage portion and electrical ground. The voltage divider also comprises a signal contact, electrically arranged between the high-voltage portion and the low-voltage portion, for providing a signal voltage indicative of the AC voltage. The low-voltage portion further comprises a plurality of electrically actuated adjustable impedance elements configured to adjust the common overall impedance of the low-voltage portion towards a desired impedance. Each electrically actuated adjustable impedance element comprises one or more associated adjustment capacitors and at least one electrically actuatable element, wherein each electrically actuatable element is associated with and electrically connected to one or more of the adjustment capacitors and wherein each electrically actuatable element is configured to achieve one of a connected state and a disconnected state. In the connected state, an associated adjustment capacitor is electrically connected in parallel to at least one of the one or more low-voltage capacitors. In the disconnected state, the associated adjustment capacitor is electrically disconnected from the low-voltage capacitor(s).

Each of the adjustment capacitors can be electrically connected in parallel, through its associated electrically actuatable element, to a low-voltage capacitor (or to a plurality of low-voltage capacitors). Adding the capacitance of the adjustment capacitor increases the capacitance of the low-voltage portion of the voltage divider and reduces its impedance, whereby the dividing ratio of the voltage divider becomes larger.

Providing a suitable number of adjustment capacitors of suitable respective impedances, each of which can be individually connected, by an associated electrically actuatable element, in parallel to one or more of the low-voltage capacitors, alone or in addition to other adjustment capacitors already connected in parallel, allows one to reduce or trim the overall accumulated impedance of the low-voltage portion and thereby allows to increase the dividing ratio T of the voltage divider to a desired, predetermined dividing ratio. The limits of this adjustment of the dividing ratio are given by the number of adjustment capacitors and their respective impedances, and by the accumulated impedance of the low-voltage capacitors.

For embodiments where there are more than one low voltage capacitors, the low voltage capacitors can be electrically connected in series or in parallel.

Several different types of electrically actuatable elements are described herein. In one aspect of the invention, each electrically actuatable element of the voltage divider comprises first and second Zener diodes connected in series with the adjustment capacitor and arranged in a back-to-back orientation. When arranged in this manner, an open circuit is provided, thus disconnecting the associated adjustment capacitor from the low voltage capacitor(s). Alternatively, in order to adjust the overall impedance of the low voltage capacitors, one or more electric pulses may be used to disable or “zap” one or more groups of first and second Zener diodes, thereby connecting the associated adjustment capacitors to the low voltage capacitors. When an adjustment capacitor is disconnected from the low-voltage capacitor(s), this disconnection results in a higher overall accumulated impedance of the low-voltage portion and thereby in a smaller dividing ratio T of the voltage divider. Disconnection of one or more individual adjustment capacitors from the low-voltage portion can facilitate obtaining a desired, predetermined dividing ratio of the voltage divider.

For example, after being brought from its disconnected (open circuit) state into its connected state, or vice versa, a zapped Zener diode keeps its state under normal operating conditions, i.e., under environmental conditions in cable accessories such as terminations, switchgears or transformers of power networks.

An adjustment capacitor is a regular capacitor that is electrically connected with an associated electrically actuatable element such that it can be electrically connected in parallel to the low-voltage portion of the voltage divider, or to at least one of the low-voltage capacitors, by bringing the electrically actuatable element into its connect state. When the electrically actuatable element is in its disconnect state, the adjustment capacitor is not connected in parallel to the low-voltage portion of the voltage divider, or to at least one of the low-voltage capacitors.

An adjustment capacitor may be a discrete capacitor, a surface-mount capacitor, a through-hole capacitor or an embedded capacitor. Its electrodes may, for example, be formed by conductive traces or conductive areas in a support, e.g. on a circuit board or on a PCB (printed circuit board).

A discrete capacitor is a capacitor that exists without other elements having to be present to form the capacitor. In particular it may exist independent of a printed circuit board or conductive traces on a PCB or on other elements. Generally, a discrete impedance element is an impedance element that exists without other elements having to be present to form the impedance element. In particular it may exist independent of a printed circuit board or conductive traces on a PCB or on other elements.

Electrically actuatable elements are electrical elements or devices that may be actuated by an electrical signal, such as an electrical pulse. This type of actuation prevents the need to utilize a robot or similar device to physically articulate a switch position, which would be required for mechanically operated switches, in which a mechanic action brings the switch from its connect state into its disconnect state or vice versa, such as dip switches.

In embodiments in which one or more of the adjustment capacitors are supported on a PCB, an associated electrically actuatable element to one or more of the adjustment capacitors may be supported on the PCB.

An electrically actuatable element is considered associated to an adjustment capacitor if the electrically actuatable element, by bringing it into its connect state, electrically connects this adjustment capacitor in parallel to at least one of the one or more low-voltage capacitors or low-voltage resistors or low-voltage impedance elements of the voltage divider.

A low-voltage capacitor, as opposed to an adjustment capacitor, is part of the low-voltage portion from the outset, and before any electrically actuatable element is brought into its connect state.

The common overall impedance of the low-voltage portion of the voltage divider is the electrical impedance of the entire low-voltage portion including the contribution to the overall impedance of those adjustment capacitors or of those adjustment resistors which are electrically connected in parallel to any of the low-voltage capacitors or low-voltage resistors. The common overall impedance also includes contributions of any resistors or inductances that might be electrically connected to any of the low-voltage capacitors and contributions of any capacitors or inductances that might be electrically connected to any of the low-voltage resistors.

The dividing ratio T of the voltage divider is a dimensionless number that is obtained by dividing the sum of the overall impedances of the high-voltage portion and of the low-voltage portion by the value of the common overall impedance of the low-voltage portion by: T=(Z_{LV}+Z_{HV})/Z_{LV}. For a given temperature of the voltage divider and a given frequency of the AC voltage, the high-voltage portion of the voltage divider is assumed to have a fixed impedance Z_{HV}. In order to obtain a voltage divider that has a desired dividing ratio T*, the common overall impedance Z_{LV} of the low-voltage portion is adjusted suitably to a desired impedance Z_{LV}* for (Z_{LV}*+Z_{HV})/Z_{LV}* to be equal to the desired dividing ratio T*. This adjustment of Z_{LV} is done by adding the impedances of selected ones of the adjustment capacitors or adjustment resistors to the impedance of the low-voltage portion, which in turn is done by bringing the respective associated switches of these selected adjustment capacitors/resistors into their connect states. The closing of these switches makes these adjustment capacitors/resistors part of the low-voltage portion.

In certain embodiments of a voltage sensor according to this disclosure, the plurality of adjustment capacitors comprises at least four adjustment capacitors, or wherein the plurality of adjustment capacitors comprises at least ten adjustment capacitors. In certain embodiments of a voltage sensor according to this disclosure, the plurality of adjustment resistors comprises at least four adjustment resistors, or wherein the plurality of adjustment resistors comprises at least ten adjustment resistors. A greater number of adjustment capacitors/resistors may allow for a finer adjustment of the common overall impedance of the low-voltage portion and thus a finer adjustment of the dividing ratio of the voltage divider.

In certain embodiments of a voltage sensor according to this disclosure, each adjustment capacitor is associated to one electrically actuatable element, and each electrically actuatable element is associated to one adjustment capacitor. A one-to-one assignment may facilitate greater control over the adjustment of the overall impedance of the low-voltage portion. It may also make the layout of the corresponding circuitry easier.

In certain embodiments of a voltage sensor according to this disclosure, two electrically actuatable elements are associated to one adjustment capacitor, such that each of the two electrically actuatable elements can connect the adjustment capacitor in parallel to at least one of the one or more low-voltage capacitors. This configuration may provide redundancy or may enhance reliability of the voltage sensor.

In certain embodiments of a voltage sensor according to this disclosure, each adjustment capacitor has a capacitance of between 0.05% and 50% of the combined capacitance of the one or more low-voltage capacitors. Adjustment capacitors having electrical capacitances in this range may be particularly suitable to provide for a wide range of adjustment possibilities of the common overall impedance of the low-voltage portion of the voltage divider, both at coarser granularities and at fine granularities. This may enhance the versatility of the voltage sensor or may allow for use of cheaper, lower-accuracy-rated low-voltage capacitors or cheaper, lower-accuracy-rated high-voltage capacitors.

In certain embodiments of a voltage sensor according to this disclosure, each adjustment capacitor has a capacitance of between 0.2 nanofarad (nF) and 100 nF. Such adjustment capacitors may be particularly advantageous when adjusting the dividing ratio of a voltage divider in networks where the AC voltage has a common amplitude (e.g. 12 kV) and the signal voltage is supposed to be in a commonly required range, e.g. of between 1 and 10 Volt.

The so-called “E series” is a system of preferred values derived for use in electronic components. It consists of the E1, E3, E6, E12, E24, E48, E96 and E192 series, where the number after the ‘E’ designates the quantity of value “steps” in each series. Although it is theoretically possible to produce components of any value, in practice the need for inventory simplification has led the industry to settle on the E series for resistors, capacitors, and inductors. The E series of preferred numbers were chosen such that when a component is manufactured it will end up in a range of roughly equally spaced values on a logarithmic scale. Each E series subdivides the interval from 1 to 10 (decade) into steps of 3, 6, 12, 24, 48, 96, 192. An exemplary E6 series uses the values 1.0, 1.5, 2.2, 3.3, 4.7, and 6.8.

In certain embodiments of a voltage sensor according to this disclosure, the capacitances of the adjustment capacitors are equally spaced on a logarithmic scale. In certain of these embodiments, the capacitance values of the adjustment capacitors are equally spaced on a logarithmic scale, e.g. represented by an E6 series. In certain embodiments of a voltage sensor according to this disclosure, the resistance values of the adjustment resistors are equally spaced on a logarithmic scale. In certain of these embodiments, the resistances of the adjustment resistors are equally spaced on a logarithmic scale, e.g. represented by an E6 series.

In certain embodiments of a voltage sensor according to this disclosure, each adjustment capacitor has a capacitance which is different from the respective capacitances of all other adjustment capacitors. This may allow for a finer granularity and accuracy in adjusting the overall impedance of the low-voltage portion and the dividing ratio of the voltage divider.

In certain embodiments of a voltage sensor according to this disclosure, the overall impedance of the high-voltage portion and the overall impedance of the low-voltage portion of the voltage divider are adapted such that, by bringing one or more of the electrically actuatable elements into their connect state, the voltage divider has, for an AC voltage of between 5 and 25 kV phase-to-ground and a frequency of between 40 and 70 Hertz, a dividing ratio of 3077±0.5% or of 6154±0.5% or of 6769±0.5% or of 10000±0.5%. These dividing ratios help provide signal voltages that can be processed with existing, off-the-shelf equipment and thereby help to meet dominant market needs. In certain of these embodiments the true dividing ratio T is within 0.5% of the desired dividing ratio T*, where this precision is obtained by selecting a suitable precision rating of the low-voltage capacitor(s) and a suitable set of adjustment capacitors and by connecting, using the electrically actuatable element, suitable ones of the adjustment capacitors in parallel to the low-voltage capacitor(s).

In certain embodiments of a voltage sensor according to this disclosure, at least one electrically actuatable element of the plurality of electrically actuatable elements, after bringing it into its connect state, cannot be brought back from its connect state into its disconnect state. An irreversible adjustment may, under specific circumstances, be instrumental in avoiding tampering, as well as sabotage, other intentional misadjustment or accidental misadjustment after installation.

In certain embodiments of a voltage sensor according to this disclosure, at least one of the electrically actuatable elements includes a set of dual Zener diodes arranged in a back-to-back manner and connected in series with an adjustment capacitor. Each dual Zener diode set can thus operate as an anti-fuse (nominally open, one-time programmable element).

In certain other embodiments of a voltage sensor according to this disclosure, at least one of the electrically actuatable elements includes a breakable fuse connected in series with an adjustment capacitor.

In certain other embodiments of a voltage sensor according to this disclosure, at least one of the electrically actuatable elements includes a breakable fuse and an inductor connected in series with an adjustment capacitor.

In certain other embodiments of a voltage sensor according to this disclosure, at least one of the electrically actuatable elements includes a field effect transistor connected in series with an adjustment capacitor.

In certain other embodiments of a voltage sensor according to this disclosure, at least one of the electrically actuatable elements includes an electromagnetic relay connected in series with an adjustment capacitor.

In certain other embodiments of a voltage sensor according to this disclosure, at least one of the electrically actuatable elements includes a MEMS relay connected in series with an adjustment capacitor.

In certain other embodiments of a voltage sensor according to this disclosure, the low-voltage portion further comprises a plurality of magnetically actuated adjustable impedance elements configured to adjust the common overall impedance of the low-voltage portion towards a desired impedance. Each magnetically actuated adjustable impedance element comprises one or more associated adjustment capacitors and at least one magnetically actuatable element, wherein each magnetically actuatable element is associated with and electrically connected to one or more of the adjustment capacitors and wherein each magnetically actuatable element is configured to achieve one of a connected state and a disconnected state. In the connected state, an associated adjustment capacitor is electrically connected in parallel to at least one of the one or more low-voltage capacitors. In the disconnected state, the associated adjustment capacitor is electrically disconnected from the low-voltage capacitor(s). In certain embodiments, at least one of the magnetically actuatable elements includes a reed switch activatable by magnetic force and connected in series with the adjustment capacitor.

In certain other embodiments of a voltage sensor according to this disclosure the voltage sensor is implemented in a sensored insulation plug for being inserted into a rear cavity of a medium voltage or high voltage separable connector in a power distribution network.

In certain embodiments of a voltage sensor according to this disclosure, at least one electrically actuatable element is adapted and/or arranged such that it can be brought into a connect state through the use of an electrical pulse. For example, in certain embodiments, the electrically actuatable element includes a set of dual Zener diodes arranged in a back-to back-manner. Careful selection of the Zener voltage of the diodes is recommended due to their reverse capacitance, which could influence the sensor ratio with varying temperature or applied voltage. Suitable, commercially available SMT Zener diodes are relatively inexpensive, <$0.10 USD each.

A Zener diode is “zapped” with an electrical pulse by exceeding its Zener voltage with sufficient current such that the Zener diode is altered into a low resistance link. For example, experimentation on SOT23 SMT dual T Zener has shown resistances about 2 to 10 ohms after zapping.

In certain embodiments of a voltage sensor according to this disclosure, the adjustment capacitors and the electrically actuatable elements are arranged on a printed circuit board (PCB). Arrangement on a PCB may help provide a rugged support for the capacitors and electrically actuatable elements. Also, PCBs are widely available and circuitry can be manufactured at low cost on PCBs, resulting in lower manufacturing cost of the voltage sensor.

In certain embodiments of a voltage sensor according to this disclosure, the printed circuit board has an elongated shape such that it can be accommodated in a cable. Accommodation in a cable can save space and may help provide environmental protection of the PCB and the electrical elements arranged on it.

In certain embodiments of a voltage sensor according to this disclosure, the printed circuit board has a shape corresponding to the cross-sectional shape (from a top or bottom view) of an insulation plug configured to be inserted into a rear cavity of a medium voltage or high voltage separable connector. In this manner, the printed circuit board may be embedded in the plug body after the impedance adjustment or trimming operation.

In certain embodiments of a voltage sensor according to this disclosure, the printed circuit board has output pads, arranged and shaped to be soldered to pins of a connector, e.g. of an M12 connector. A direct mechanical and electrical connection of the PCB to a connector may make the use of an intermediate cable obsolete and may thereby help reduce the number of soldering points and increase the mechanical stability of the assembly of PCB and connector, thereby increasing reliability of the voltage sensor.

The present invention also provides a power network for distributing electrical power in a national grid, the power network comprising an HV/MV power conductor and a voltage sensor as described herein, the voltage sensor being electrically connected to the power conductor to sense an AC voltage of the power conductor. Power networks incorporating a voltage sensor as described herein may be operated more efficiently due to accurate knowledge about the voltage in certain power conductors of the network.

The present invention also provides a method of adjusting or calibrating the common overall impedance of the low-voltage portion of the voltage divider of a voltage sensor as described herein towards a desired impedance, the method comprising the steps of determining which electrically actuatable elements to actuate and bringing at least one of the electrically actuatable elements into the connect state or into the disconnect state.

### BRIEF DESCRIPTION OF THE DRAWINGS

The invention will now be described in more detail with reference to the following figures exemplifying particular embodiments of the invention:

FIG. 1 is a schematic circuit diagram of a capacitive voltage sensor according to an embodiment of the invention;

FIG. 2A is a schematic diagram of an electrically actuatable element comprising a dual Zener diode arrangement according to an embodiment of the present invention;

FIG. 2B is a schematic circuit diagram of a capacitive voltage sensor according to another embodiment of the present invention;

FIG. 3A is a sectional view of a separable connector and a first sensored insulation plug according to another embodiment of the present invention;

FIG. 3B is a cross-section, schematic view of a sensored insulation plug according to another embodiment of the present invention;

FIG. 4A is a schematic diagram of an electrically actuatable element comprising a breakable fuse according to an alternative embodiment of the present invention;

FIG. 4B is a schematic diagram of an electrically actuatable element comprising a breakable fuse and inductor according to an alternative embodiment of the present invention;

FIG. 4C is a schematic diagram of an electrically actuatable element comprising a field effect transistor according to an alternative embodiment of the present invention;

FIG. 4D is a schematic diagram of an electrically actuatable element comprising an electromagnet relay according to an alternative embodiment of the present invention.

It should be understood that numerous other modifications and embodiments can be devised by those skilled in the art, which fall within the scope and spirit of the principles of the disclosure. The figures may not be drawn to scale.

### DETAILED DESCRIPTION

As used herein, the terms “preferred” and “preferably” refer to embodiments described herein that can afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the invention.

As used herein and in the appended claims, the singular forms “a,” “an,” and “the” include plural referents unless the context clearly dictates otherwise. Thus, for example, reference to “a” or “the” component may include one or more of the components and equivalents thereof known to those skilled in the art. Further, the term “and/or” means one or all of the listed elements or a combination of any two or more of the listed elements.

It is noted that the term “comprises”, and variations thereof, do not have a limiting meaning where these terms appear in the accompanying description. Moreover, “a,” “an,” “the,” “at least one,” and “one or more” are used interchangeably herein. Relative terms such as left, right, forward, rearward, top, bottom, side, upper, lower, horizontal, and vertical may be used herein and, if so, are from the perspective observed in the particular figure. These terms are used only to simplify the description, however, and not to limit the scope of the invention in any way.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention.

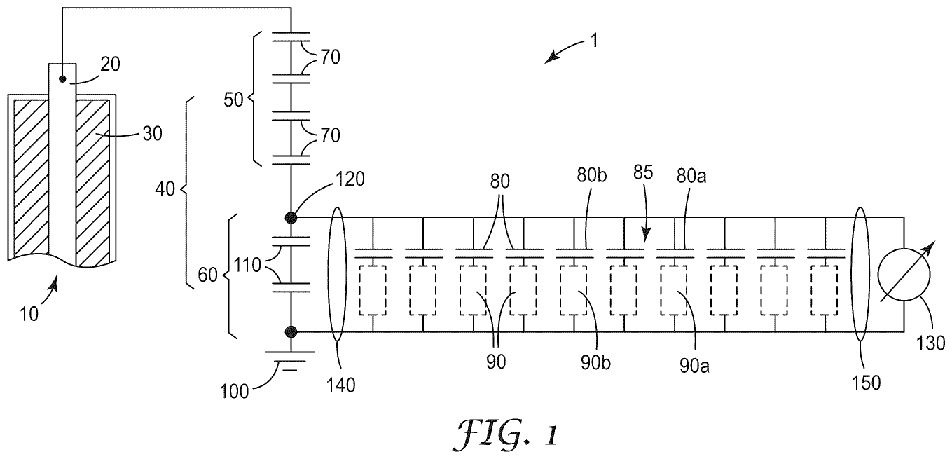

In the circuit diagram of FIG. 1, a capacitive voltage sensor 1 according to the present disclosure is illustrated. It is used for sensing an AC voltage of a high-voltage power cable 10, shown in a sectional view in FIG. 1. The cable 10 has a central conductor 20 surrounded by an insulation layer 30. In use, the central conductor 20 conducts electrical power in a national grid at an AC voltage of 12 kilovolt (kV) and at currents of hundreds of amperes.

The voltage sensor 1 is electrically connected to the central conductor 20 in order to sense the AC voltage of the conductor 20. For that sensing, the voltage sensor 1 comprises a voltage divider which in turn consists of a high-voltage portion 50 and a low-voltage portion 60. The high-voltage portion 50 is electrically connected between the AC voltage of the central conductor 20 of the power cable 10 and the low-voltage portion 60, and it comprises one or more (e.g., four) high-voltage capacitors 70, electrically connected in series with each other.

The low-voltage portion 60 is electrically connected between the high-voltage portion 50 and electrical ground 100. The low-voltage portion may comprise one or more low voltage capacitors 110. In some embodiments, a single low voltage capacitor 110 is utilized. In the embodiment of FIG. 1, two low voltage capacitors 110 are shown, electrically connected between the high-voltage portion 50 and ground 100, and in series with each other. In an alternate embodiment, low voltage capacitors 110 may be connected in parallel.

A divided voltage or “signal voltage” can be picked up at a signal contact 120, located electrically between the high-voltage portion 50 and the low-voltage portion 60. The signal voltage is indicative of the AC voltage of the conductor 20, and varies proportionally with the AC voltage, the proportionality factor being the dividing ratio of the voltage divider 40. A voltage measurement device 130 is connected between the signal contact 120 and ground 100 to measure the signal voltage. A value of the AC voltage is obtained by multiplying the signal voltage with the dividing ratio.

The low-voltage portion 60 of this embodiment also comprises one or more (e.g., ten) electrically actuated adjustable impedance elements 85, each of which includes an adjustment capacitor 80 and an electrically actuatable element 90. Each adjustment capacitor 80 can be connected in parallel to the low-voltage capacitor(s) 110 by actuating the associated electrically actuatable element.

In the embodiment shown in FIG. 1, each adjustment capacitor 80 has one electrically actuatable element 90 associated to it: the associated electrically actuatable element 90 of an adjustment capacitor 80 can comprise several different configurations, such as a dual Zener diode arrangement, as described herein. When the electrically actuatable element 90 is brought into its “connect state”, it electrically connects the adjustment capacitor 80 in parallel to the low-voltage capacitors 110. For example, the one of the electrically actuatable elements 90 which is associated to adjustment capacitor 80a is labelled electrically actuatable element 90a, because when it is actuated, such as when a dual Zener diode arrangement is “zapped”, it connects the adjustment capacitor 80a in parallel to the low-voltage capacitors 110. Unless actuated, the electrically actuatable element 90a of this example is in an open, or disconnected state.

In the disconnected state, an electrically actuatable elements disconnects one electrode of the associated adjustment capacitors 80 from the low-voltage capacitors 110. Before actuating the electrically actuatable element, the impedance of the low-voltage portion 60 is the combined impedance of the low-voltage capacitors 110, which results in a certain dividing ratio of the voltage divider 40, taking into account the impedance of the high-voltage portion 50. After actuating a particular electrically actuatable element, such as electrically actuatable element 90b, the impedance of the adjustment capacitor 80b, is now connected in parallel to the low-voltage capacitors 110, and adds to the combined impedance of the low-voltage capacitors 110 according to the known laws of electricity, resulting in a smaller overall impedance of the low-voltage portion 60 and a larger dividing ratio T.

In order to facilitate meeting a specified dividing ratio, the adjustment capacitors 80 have different individual capacitances and hence different individual impedances. Starting from the (combined) impedance of the low-voltage capacitor(s) 110, the addition of a small impedance may be sufficient to obtain the specified dividing ratio. A user may then select to connect a selected one of the ten adjustment capacitors 80 in parallel to the low-voltage capacitor(s) 110, which adjustment capacitor 80 has the appropriate small additional impedance for the low-voltage portion 60 to have the appropriate overall impedance to provide the voltage divider 40 with the specified dividing ratio.

In some embodiments, a single adjustment capacitor 80 can be added. In other embodiments, multiple adjustment capacitors or all electrically actuatable elements 90 may be brought into their connect state to connect their associated adjustment capacitors 80 in parallel to the low-voltage capacitor(s) 110.

In alternative embodiments the low-voltage portion 60 comprises twelve adjustment capacitors 80. Two of these adjustment capacitors 80 may have individual capacitances to bring the dividing ratio roughly close to a specific desired dividing ratio T*, for example, T*=3077 or T*=6154 or T*=6769 or T*=10000, but slightly below that specific desired dividing ratio. Two electrically actuatable elements, each defining two states, can provide four different impedance combinations. In certain embodiments, each electrically actuatable element combination brings the dividing ratio roughly close to one of the four specific desired dividing ratios T*.

The remaining ten adjustment capacitors 80 have individual capacitances which are chosen appropriately to match the desired dividing ratio with an accuracy of 1%, 0.5% or 0.2%. To minimize the number of parts, the values of the capacitances of these adjustment capacitors 80 are chosen such that their nominal capacitance values are equally spaced on a scale, such as a binary scale or, alternatively, a logarithmic scale.

The voltage sensor 1 of FIG. 1 can be set to a given, desired dividing ratio at the time of manufacture by connecting its high-voltage portion to a well-known AC voltage of the intended operating frequency and the intended operating temperature, with all electrically actuatable elements in their disconnect states. Appropriate electrically actuatable elements 90 (one electrically actuatable element or several electrically actuatable elements) would then be brought into their connect states such that the signal voltage, as measured by the voltage measurement device 130, is at a voltage that is equal to the known AC voltage, multiplied by the desired dividing ratio.

The low-voltage capacitors 110 and the electrically actuated adjustable impedance elements (the adjustment capacitors 80 and the electrically actuatable elements 90) can be arranged on a printed circuit board (PCB), which PCB may be located at a distance from the physical location of the high-voltage portion 50. Alternatively, only the adjustment capacitors 80 and the electrically actuatable elements 90 can be arranged on a printed circuit board. The PCB could be located at a distance from the physical location of the low-voltage capacitors 110. A signal cable, indicated by 140, could lead signal wires from the signal contact 120 and the sensor ground 100 from the output of the low-voltage capacitors 110 to the PCB, and an output cable 150 could lead wires from the PCB output to the voltage measurement device 130.

In certain embodiments the adjustment capacitors 80 and the electrically actuatable elements are grouped physically next to each other and form a “calibration unit”. This calibration unit may comprise a printed circuit board (PCB) on which the adjustment capacitors 80 and the electrically actuatable elements 90 are arranged and supported. In addition, each electrically actuatable element can further be coupled to one or more adjacent test points, which provide access for test pins or probes to send the actuating electrical pulse to a desired one or more of the electrically actuatable elements.

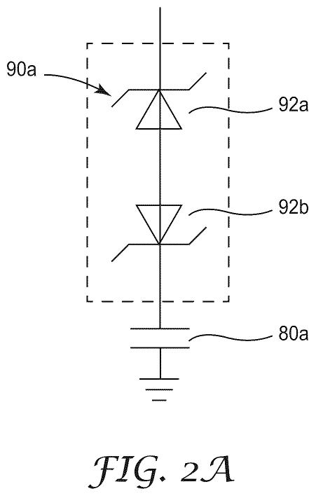

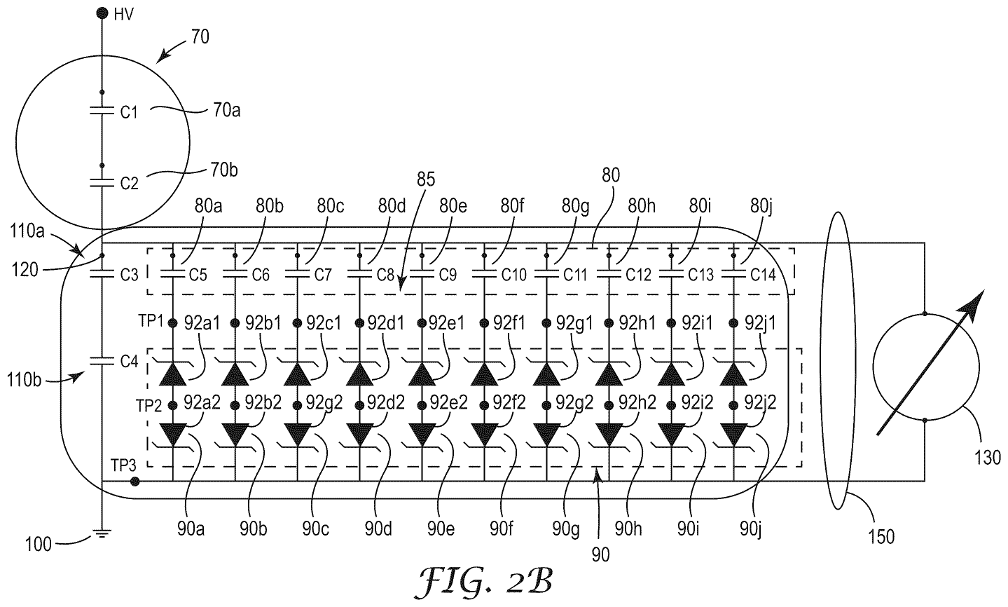

FIG. 2A illustrates, in a schematic view, an exemplary embodiment of an electrically actuated adjustable impedance element that comprises an adjustment capacitor 80a and an associated electrically actuatable element 90a. In this embodiment, the electrically actuatable element comprises dual Zener diodes 92a and 92b arranged in a back-to-back manner and connected in series with adjustment capacitor 80a. As the diodes are arranged in a back-to-back manner, they will block AC voltages. By feeding a DC current pulse through the diodes, conductive paths are established in the pn-junctions. This method is also referred to as “Zener zapping.” In one example, the Zener diodes comprise SMT Zener diodes. Particular diodes can be selected based on their reverse capacitance, which can influence the sensor ratio with varying temperature or applied voltage. A brief investigation of SOT23 SMT Zener diodes has shown a resistance of about 2 ohms after zapping.

As mentioned above, when the Zener diodes are placed on a PCB, adjacent or nearby test points can also be provided so that a test adapter or calibration unit with, e.g., pogo pins, can make contact to the test points. In this manner, a programmable relay can be used to determine which Zener diodes need to be actuated/zapped. In addition, the same test adapter can be used to perform the zapping step.

Another embodiment of the present invention is shown in FIG. 2B, which shows a circuit diagram of the voltage divider portion of the voltage sensor. Similar to the voltage sensor of FIG. 1, the voltage sensor of FIG. 2B is electrically connected to the central conductor (such as conductor in order to sense the AC voltage of the conductor. For that sensing, the voltage sensor comprises a voltage divider, which in turn includes of a high-voltage portion and a low-voltage portion. The high-voltage portion is electrically connected between the AC voltage of the central conductor of the power cable and the low-voltage portion. In this embodiment, the high voltage portion comprises one of more high voltage capacitors 70. In this case capacitors 70a and 70b electrically connected in series with each other.

The low-voltage portion is electrically connected between the high-voltage portion and electrical ground 100. In this example, the low voltage portion comprises two low-voltage capacitors 110a and 110b, electrically connected between the high-voltage portion and ground 100, and in series with each other.

A divided voltage or “signal voltage” can be picked up at a signal contact 120, located electrically between the high-voltage portion and the low-voltage portion. The signal voltage is indicative of the AC voltage of the conductor, and varies proportionally with the AC voltage, the proportionality factor being the dividing ratio of the voltage divider. A voltage measurement device 130 is connected between the signal contact 120 and ground 100 to measure the signal voltage. A value of the AC voltage is obtained by multiplying the signal voltage with the dividing ratio.

The low-voltage portion of this embodiment also comprises one or more (e.g., ten, in this example) electrically actuated adjustable impedance elements 85, each of which includes an adjustment capacitor 80a-80j and an electrically actuatable element 90a-90j, with each electrically actuatable element having the form of dual Zener diodes arranged in a back-to-back manner and connected in series with the associated adjustment capacitor. Of course, the low voltage portion of other embodiments may include fewer (e.g., 4, 5, 6, etc.) or greater (e.g., 11, 12, 13, etc.) numbers of adjustment capacitors, depending on the particular application or implementation.

For example, electrically actuatable element 90a comprises dual Zener diodes 92a1 and 92a2 that are arranged in a back-to-back manner and connected in series with adjustment capacitor 80a. In addition, electrically actuatable element 90b comprises dual Zener diodes 92b1 and 92b2 that are arranged in a back-to-back manner and connected in series with adjustment capacitor 80b, electrically actuatable element 90c comprises dual Zener diodes 92c1 and 92c2, and so forth. In addition, multiple test points, such as test points TP1, TP2, and TP3, can be provided to allow the test adapter to provide an electrical pulse to zap the dual Zener diodes 92a1 and 92a2 in the event adjustment capacitor 80a is to be utilized to adjust the impedance of the low voltage portion. In this manner, each adjustment capacitor 80a-80j can be connected in parallel to the low-voltage capacitors 110 by actuating the associated dual Zener diode arrangement.

As with the previous embodiment described with respect to FIG. 1, the voltage divider of FIG. 2B has, for each adjustment capacitor 80a-80j, an electrically actuatable element 90a-90j associated to it. When the electrically actuatable element 90a-90j is brought into its “connect state” (e.g., through “zapping” the dual Zener diodes), it electrically connects the adjustment capacitor 80a-80j in parallel to the low-voltage capacitors 110a, 110b. Unless actuated, the electrically actuatable element 90a-90j of this example is in an open, or disconnected state.

In the disconnected state, an electrically actuatable element disconnects one electrode of the associated adjustment capacitor 80 from the low-voltage capacitors 110a, 110b. Before actuating the electrically actuatable element, the impedance of the low-voltage portion is the combined impedance of the low-voltage capacitors 110a, 110b, which results in a certain dividing ratio of the voltage divider, taking into account the impedance of the high-voltage portion. After actuating one or more electrically actuatable elements, such as electrically actuatable element 90a and 90b, the impedance of the adjustment capacitors 80a and 80b are now connected in parallel to the low-voltage capacitors 110a, 110b, and add to the combined impedance of the low-voltage capacitors, resulting in a smaller overall impedance of the low-voltage portion and a larger dividing ratio T.

In order to facilitate meeting a specified dividing ratio, the adjustment capacitors 80a-80j have different individual capacitances (C5-C14) and hence different individual impedances. A user may then select to connect a selected one or more of the ten adjustment capacitors 80a-80j in parallel to the low-voltage capacitors 110a, 110b, which adjustment capacitor(s) has the appropriate small additional impedance for the low-voltage portion to have the appropriate overall impedance to provide the voltage divider with the specified dividing ratio.

The ten adjustment capacitors 80a-80j have individual capacitances which are chosen appropriately to match the desired dividing ratio with an accuracy of 1%, 0.5% or 0.2%. To minimize the number of parts, the values of the capacitances of these adjustment capacitors 80a-80j are chosen such that their nominal capacitance values are equally spaced on a logarithmic scale, e.g. represented by an E6 series.

As with the example of FIG. 1, the voltage sensor 1 of FIG. 2B can be set to a given, desired dividing ratio at the time of manufacture by connecting its high-voltage portion to a well-known AC voltage of the intended operating frequency and the intended operating temperature, with all electrically actuatable elements 90a-90j in their disconnect states. Appropriate electrically actuatable elements 90a-90j would then be brought into their connect states such that the signal voltage, as measured by the voltage measurement device 130, is at a voltage that is equal to the known AC voltage, multiplied by the desired dividing ratio.

The low-voltage capacitors 110a, 110b and the electrically actuated adjustable impedance elements (the adjustment capacitors 80a-80j and the electrically actuatable elements 90a-90j) can be arranged on a printed circuit board (PCB), which PCB may be located at a distance from the physical location of the high-voltage portion. Alternatively, only the adjustment capacitors 80a-80j and the electrically actuatable elements 90a-90j can be arranged on a printed circuit board. The PCB could be located at a distance from the physical location of the low-voltage capacitors 110a, 110b. A signal cable could lead signal wires from the signal contact 120 and the sensor ground 100 from the output of the low-voltage capacitors 110a, 110b to the PCB, and an output cable 150 could lead wires from the PCB output to the voltage measurement device 130.

In certain embodiments the adjustment capacitors 80a-80j and the electrically actuatable elements 90a-90j are grouped physically next to each other and form a calibration unit. This calibration unit may comprise a PCB on which the adjustment capacitors 80a-80j and the electrically actuatable elements 90a-90j are arranged and supported. In addition, each electrically actuatable element can further be coupled to one or more adjacent test points (e.g., TP1, TP2, TP3), which provide access for test pins or probes to send the actuating electrical pulse to a desired one or more of the electrically actuatable elements.

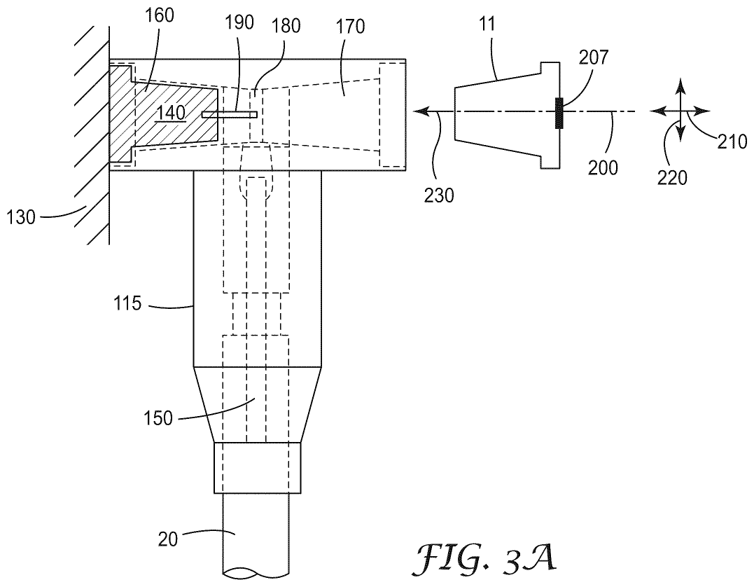

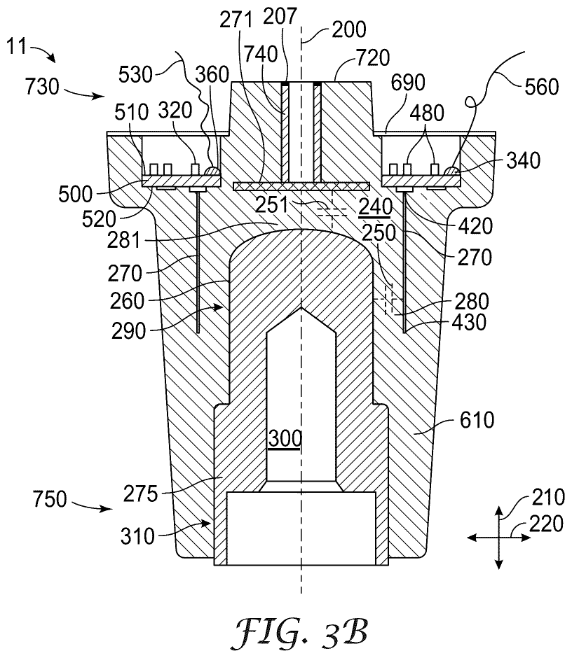

As mentioned above, the voltage sensor of the present invention can be implemented in a sensored insulation plug. FIG. 3A shows a separable connector 115 and a first sensored insulation plug 11 according to the present disclosure. The separable connector 115 is arranged at an end of a medium-voltage power cable 20 and connects, via a bushing 140, the power-carrying central conductor 150 of the cable 20 to a medium-voltage switchgear 130 in a power distribution network of a national grid.

The separable connector 115 is a T-shaped separable connector 115 and comprises a front cavity 160 for receiving the bushing 140, and a rear cavity 170 for receiving an insulation plug of a matching shape. The insulation plug may be a traditional insulation plug without elements of a sensor or a sensored insulation plug 11 according to the present disclosure, shown in FIG. 3A to the right of the rear cavity 170, before being inserted into the rear cavity 170. A traditional insulation plug and a sensored insulation plug 11 according to the present disclosure both serve to electrically insulate a connection element 180 of the separable connector 115, which is electrically connected to the central conductor 150 of the cable 20 and can be electrically and mechanically connected to a conductive component of the bushing 140 via a threaded stud 190. In use, the connection element 180 is on the elevated voltage of the central conductor 150 of the cable.

The first sensored insulation plug 11, just like a traditional insulation plug, has an overall frustoconical outer shape, generally rotationally symmetric about a plug axis 200 which defines axial directions 210 and radial directions 220, which are directions orthogonal to the axial directions 210. The sensored insulation plug 11 can be inserted into the rear cavity 170 by moving it axially in an axial insertion direction 230 into the rear cavity 170 where it is turned by several revolutions about the plug axis 200 to be threadedly engaged—and thereby electrically connected—with the connection element 180 on elevated voltage. The geometry of the sensored insulation plug 11 is adapted to conform to IEEE standard 386 to be suitable for a greater number of separable connectors. Depending on where the sensored insulation plug 11 is to be used, it could alternatively be adapted to conform to other standards or be adapted to fit into the most common types of separable connectors in a specific area of the world.

The sensored insulation plug 11 comprises a primary capacitor 250. Optionally, the sensored insulation plug 11 can also comprise a testpoint capacitor 251. The primary capacitor and optionally the testpoint capacitor can be electrically connected to the connection element 180 on elevated voltage. The primary capacitor is operable as a high-voltage capacitor in a sensing voltage divider for sensing the elevated voltage, and the testpoint capacitor is operable as a high-voltage capacitor in a detection voltage divider for detecting the elevated voltage.

The sensored insulation plug 11 comprises, at its low-voltage end portion, a detection contact 207 that is accessible for being contacted by a hotstick via which the elevated voltage can be detected and indicated to a human installer.

FIG. 3B shows, in a sectional view, the first sensored insulation plug 11. The sensored insulation plug 11 comprises a plug body 240 of an insulating material 610, namely an electrically insulating hardened resin 610, a primary capacitor 250 formed by a high-voltage electrode 260 and a tubular sensing electrode 270, and a testpoint capacitor 251 formed by the high-voltage electrode 260 and, optionally, a disk-shaped testpoint electrode 271.

The high-voltage electrode 260, the sensing electrode 270, and the testpoint electrode 271 are rotationally symmetric about a plug axis 200. The dielectric of the primary capacitor 250 is formed by a first portion 280 of the insulating material 610 of the plug body 240, located between the high-voltage electrode 260 and the sensing electrode 270. The dielectric of the testpoint capacitor 251 is formed by a second portion 281 of the insulating material 610 of the plug body 240, located between the high-voltage electrode 260 and the testpoint electrode 271.

The high-voltage electrode 260 is comprised in an electrode portion 290 of a contact piece 275 made of conductive metal. The contact piece 275 is generally rotationally symmetric about the plug axis 200 and has, further to the electrode portion 290, an engagement portion 310 for mechanical engagement with an intermediate element connecting the contact piece 275 electrically with the connection element 180 of the separable connector 115. The electrode portion 290 forms the high-voltage electrode 260. The engagement portion 310 and the electrode portion 290 are formed as a single piece of metal.

The contact piece 275 comprises a threaded recess 300 to connectingly engage a stud 190 for mechanical and direct, i.e. ohmic, electrical connection of the contact piece 275 to the connection element 180 of the separable connector 115. In use, the entire contact piece 275 and in particular its electrode portion 290 are on the elevated voltage of the connection element 180 of the separable connector 115.

The sensing electrode 270 comprises a mesh 270 of conductive stainless-steel wires. It has a generally tubular shape and is arranged concentrically around the high-voltage electrode 260. A proximal edge 420 of the sensing electrode 270 is attached to a supporting circuit board 500, while a distal edge 430 is axially spaced from the circuit board 500 by the length of the sensing electrode 270. The length of the sensing electrode 270 is its extension in axial direction 210. In this embodiment, the circuit board 500 can include the low voltage portion of the capacitive voltage divider and the electrically actuated adjustable impedance elements described previously with respect to FIGS. 1, 2B.

In one embodiment, the testpoint electrode 271 can be formed from a metal plate material having holes formed therein. Alternatively, the testpoint electrode 271 can be formed from a mesh of conductive stainless-steel wires forming apertures between them. The testpoint electrode 271 is flat and has the shape of a circular disk, centered on the plug axis 200. The apertures extend through the testpoint electrode 271 in its thickness direction, which is an axial direction 210 in the illustrated embodiment. In axial directions 210, the testpoint electrode 271 is arranged opposite to the high-voltage electrode 260, spaced by a couple of millimeters. The space between the testpoint electrode 271 and the high-voltage electrode 260 is filled with insulating material 610, so that the testpoint electrode 271, the high-voltage electrode 260 and the insulating material 610 between them form a capacitor, namely the testpoint capacitor 251.

The sensing electrode 270 and the testpoint electrode 271 are each completely surrounded by the insulating material 610 of the plug body 240. In other words, they are each embedded in the plug body 240. The major surfaces of the sensing electrode 270 and the major surfaces of the testpoint electrode 271 are in surface contact with the surrounding insulating material 610 of the plug body 240 in which the sensing electrode 270 and the testpoint electrode 271 are embedded.

In particular, a first portion 280 of the insulating material 610 is present between the sensing electrode 270 and the high-voltage electrode 260, so that the first portion 280 of the insulating material 610 forms a dielectric of the primary capacitor 250, and a second portion 281 of the insulating material 610 is present between the testpoint electrode 271 and the high-voltage electrode 260, so that that second portion 281 of the insulating material 610 forms a dielectric of the testpoint capacitor 251.

The insulating material 610 of the plug body 240 is a hardened epoxy resin. In manufacturing, the resin in its liquid state is cast or molded around the high-voltage electrode 260, the sensing electrode 270 and the testpoint electrode 271 in a mold that determines the outer shape of the sensored insulation plug 11. A major part of the resin 610 flows under pressure towards and around the mesh 270 of the sensing electrode 270 and towards and around the material of the testpoint electrode 271, and portions of the resin fill the apertures between the wires of the respective meshes 270, 271. These portions thus connect insulating material 610 radially inside the sensing electrode 270 with insulating material 610 radially outside the sensing electrode 270 and connect insulating material 610 above the testpoint electrode 271 with insulating material 610 below the testpoint electrode 271. “Above” and “below” refer to the orientation of the sensored insulation plug as drawn in FIG. 3B. The resin 610 is then cured or hardened to solidify, resulting in a solid insulating plug body 240 in which the sensing electrode 270 and the testpoint electrode 271 are embedded.

The apertures between the wires of the respective meshes 270, 271 facilitate, during production of the sensored insulation plug 11, the flow of liquid insulating material 610 into the space between the sensing electrode 270 and the high-voltage electrode 260 and into the space between the testpoint electrode 271 and the high-voltage electrode 160, respectively. Portions of the insulating material 610 remaining in the apertures later connect insulating material 610 on one side of the respective electrode 270, 271 with insulating material 610 on the other side of the respective electrode 270, 271.

The electrical breakdown strength of the insulating material 610 is high enough to reliably prevent electric discharges between the high-voltage electrode 260 on elevated voltage and the sensing electrode 270 and between the high-voltage electrode 260 on elevated voltage and the testpoint electrode 271.

The sensing electrode can comprise one or more different constructions. In one embodiment, the sensing electrode 270 can be coupled to a metal plate of suitable thickness bolted in place. In another embodiment, the sensing electrode 270 can be mechanically supported by a flat, rigid circuit board 500 of generally annular shape, arranged concentrically with the plug axis 200. The circuit board 500 comprises conductive traces by which electric and electronic components 480, such as the sensing electrode 270, arranged respectively on the upper surface 510 and on the lower surface 520 of the circuit board 500, are electrically connected with each other. In particular, one or more low-voltage capacitor(s) 320 are arranged on the upper surface 510 of the circuit board 500. This low-voltage capacitor(s) 320 is electrically connected in series between the sensing electrode 270 and a grounding contact 340 held on electrical ground 350. The grounding contact 340 on the circuit board 500 can be connected to an external grounding point via a grounding wire 560 leading from the grounding contact 340 through an aperture in a grounded conductive lid 690 to outside the sensored insulation plug 11.

In one embodiment, the low-voltage capacitor(s) 320 forms the low-voltage portion 380 of a sensing voltage divider for sensing the elevated voltage, with the primary capacitor 250 forming the high-voltage portion 370 of the sensing voltage divider.

In some embodiments, the plug body includes cut outs or openings that provide access, such as through, e.g., a test adapter, to the electronic components 480, such as adjustment capacitors.

In some embodiments, the circuit board 500 can be embedded in the plug body 240. The electrically conductive, grounded lid 690 can help in shielding the electric and electronic components 480 on the circuit board 500 against external electrical fields.

The divided voltage of the sensing voltage divider, such as voltage divider 1 (shown in FIG. 1) can be accessed at a signal contact 360 on the circuit board 500. A signal wire 530 makes the signal voltage available outside the sensored insulation plug 11, it is led through an aperture in the grounded conductive lid 690. As is generally known for voltage dividers, the signal voltage varies proportionally with the elevated voltage of the high-voltage electrode 260, so that the elevated voltage of the high-voltage electrode 260—and thereby the elevated voltage of the connection element 180 of the separable connector 115—can be determined by measuring the signal voltage and multiplying it with the dividing ratio of the sensing voltage divider.

The voltage of the testpoint electrode 271, i.e. the detection voltage, can be picked up at a detection contact 207, arranged on an axial end face 720 of a low-voltage end portion 730 of the sensored insulation plug 11. The detection contact 207 is formed by an end portion of a conductive hollow cylindrical copper tube 740, the end portion of which is exposed and externally accessible at the end face 720. The tube 740 extends from the axial end face 720 along the plug axis 200 towards a high-voltage end portion 750 of the sensored insulation plug 11, and mechanically and electrically connects the testpoint electrode 271 with the detection contact 207. The central axis of the copper tube 740 is collinear with the plug axis 200, and the interior of the tube 740 is empty, while its radially outer surface is in surface contact with the insulating material 610 of the plug body 240.

The hollow conductive tube 740 can receive a pin-shaped or conical contact at the end of a hotstick, whereby an electrical contact is established. A detection voltage divider (not shown) is created by the serial electrical connection of the testpoint capacitor 251 and a grounded low-voltage capacitor 321 in the hotstick, or by the testpoint capacitor 251 and a “floating capacitor”, formed between the hotstick contact and ground, with ambient air as dielectric. This detection voltage divider is operable to detect presence or absence of elevated voltage on the high-voltage electrode 260 of the testpoint capacitor 251.

As mentioned previously, the electrically actuatable elements utilized in the low voltage portion of the voltage divider can take different forms, such as the dual Zener diode electrically actuatable elements described with respect to FIGS. 2A and 2B. In alternative embodiments, the electrically actuatable elements include: a breakable fuse connected in series with an adjustment capacitor; a breakable fuse and an inductor connected in series with an adjustment capacitor; a field effect transistor connected in series with an adjustment capacitor; an electromagnetic relay connected in series with an adjustment capacitor; and/or a MEMS relay connected in series with an adjustment capacitor.

In a further alternative embodiment of the present disclosure, instead of an electrically actuatable element, the low voltage portion of the voltage divider can comprise a plurality of magnetically actuated adjustable impedance elements configured to adjust the common overall impedance of the low-voltage portion towards a desired impedance. In this alternative embodiment, the magnetically actuated adjustable impedance elements can comprise a reed switch, actuatable by a permanent magnet, connected in series with an adjustment capacitor.

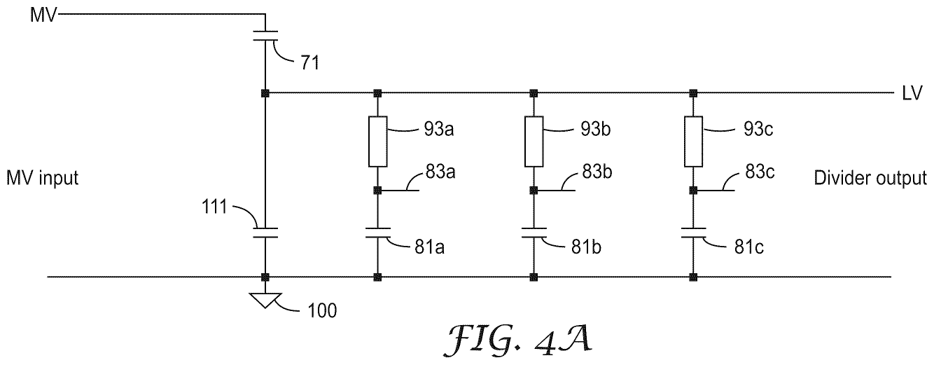

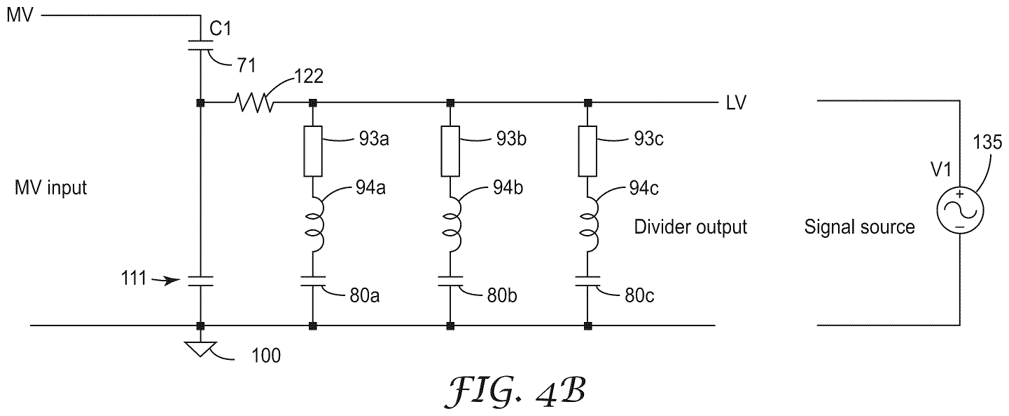

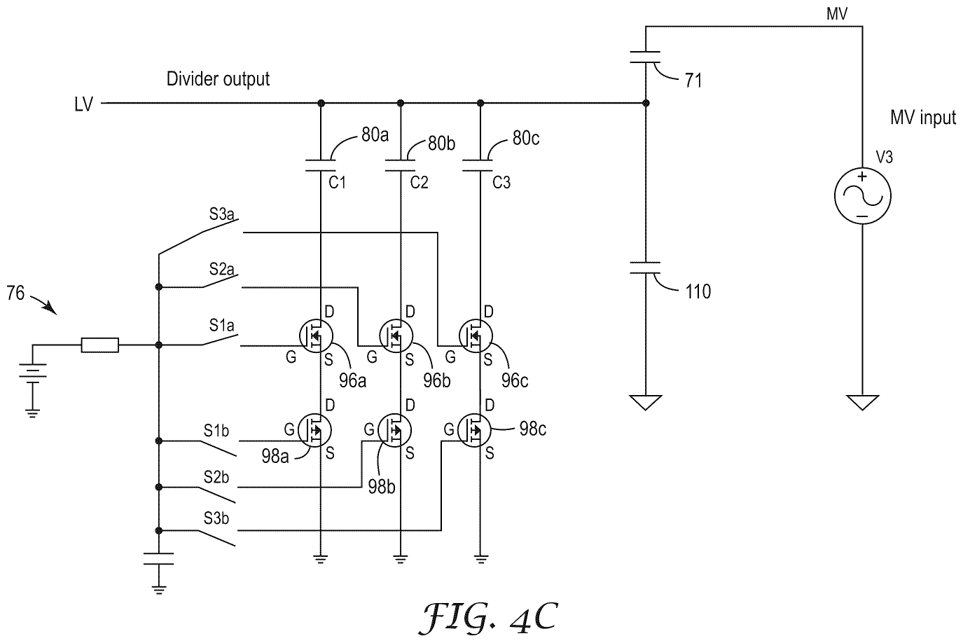

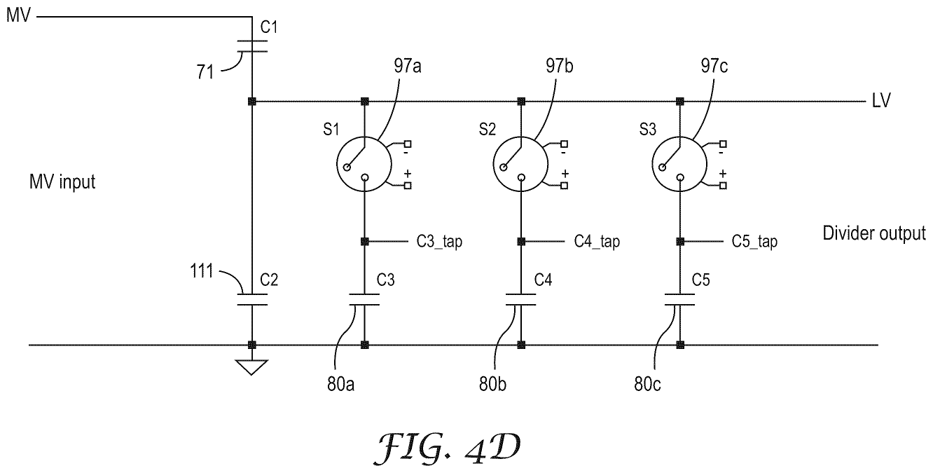

In further detail, FIG. 4A shows an example voltage divider circuit, where the low voltage portion includes a plurality of breakable fuses each connected in series with an associated adjustment capacitor. In this example, fuses are used to individually deselect adjustment capacitors. In this alternative embodiment, the fuses are configured to deliberately break connections when actuated, rather than create them. As shown in FIG. 4A, the voltage divider includes a high-voltage portion that is electrically connected between the AC voltage and the low-voltage portion. In this embodiment, the high voltage portion comprises a high voltage capacitor 71. In alternative aspects, the high-voltage portion can include multiple high-voltage capacitors electrically connected in series with each other.

The low-voltage portion is electrically connected between the high-voltage portion and electrical ground 100. In this example, the low voltage portion comprises a low-voltage capacitor 111. In alternative aspects the low voltage portion can include multiple low-voltage capacitors, electrically connected in series or in parallel with each other.

The low-voltage portion of this embodiment also comprises a plurality of electrically actuated adjustable impedance elements, each of which includes an adjustment capacitor 81a-81c and an electrically actuatable element 93a-93c, with each electrically actuatable element having the form of a breakable fuse. To blow a fuse, a DC current is run through it by the ‘LV’ connection and the dedicated tap 83a-83c disposed at the fuse. For example, to break fuse 93a, “LV” and tap 93a are connected to a DC source. In this configuration, each fuse tap can be accessed by a test adapter. Of course, the low voltage portion of other embodiments may include a different number of adjustment capacitors, depending on the particular application or implementation. In this example, a fuse can be comprise a type 459 (Littlefuse) having a resistance of about 0.13 ohm for a rated current of 1 A.

In a further alternative embodiment of the present disclosure, FIG. 4B shows an example voltage divider circuit, where the low voltage portion includes a plurality of breakable fuses each connected in series with an associated inductor and adjustment capacitor. In this example, fuses are used to individually deselect adjustment capacitors. In this alternative embodiment, the fuses are configured to deliberately break connections when actuated, rather than create them. In addition, the capacitor, inductor, and fuse's resistance can be considered as an RLC member, where each RLC member has a specific resonance frequency, and where the impedances of the inductor and capacitor are cancelled.

As shown in FIG. 4B, the voltage divider includes a high-voltage portion that is electrically connected between the AC voltage and the low-voltage portion. In this embodiment, the high voltage portion comprises a high voltage capacitor 71. In alternative aspects, the high-voltage portion can include multiple high-voltage capacitors electrically connected in series with each other.

The low-voltage portion is electrically connected between the high-voltage portion and electrical ground 100. In this example, the low voltage portion comprises a low-voltage capacitor 111. In alternative aspects the low voltage portion can include multiple low-voltage capacitors, electrically connected in series or in parallel with each other.

The low-voltage portion of this embodiment also comprises a plurality of electrically actuated adjustable impedance elements, each of which includes an adjustment capacitor 81a-81c, an electrically actuatable element 93a-93c, with each electrically actuatable element having the form of a breakable fuse connected in series with an inductor 94a-94c. In the calibration process, an AC signal source can be connected to the sensor's low voltage output. The source can be set to the resonance frequency of the RLC member. Approaching resonance, the current from the AC source blows the fuse of the resonating RLC member, thus disconnecting the associated adjustment capacitor from the circuit. The inductors can be chosen such that generated resonances are far above 50 Hz/60 Hz, so as to not interfere with the sensor operation.

Optionally, a series resistor 122 can be added between the low voltage capacitor(s) and the electrically actuated adjustable impedance elements to help with limiting the current to the low voltage capacitor(s) in certain applications.

In a further alternative embodiment of the present disclosure, FIG. 4C shows an example voltage divider circuit, where the low voltage portion includes a plurality of field effect transistors 96a-96c and 98a-98c connected in series with an associated adjustment capacitor 80a-80c. A burning (or punching) circuit 76 can be connected to the field effect transistors during the calibration process via switches S1a-S3a and S1b-S3b. In this example, field effect transistors (FETs), such as N-channel MOSFETs 96a-96c and P-channel MOSFETs 98a-98c, can be permanently actuated by burning the metal oxide layer with a DC pulse. Using FETs provides for dual use of the switching element—e.g., a first low voltage (e.g., 5V) can be used to switch on the FETs and a second higher voltage (e.g., 15V) can be used to destroy the selected FETs (to keep them permanently on). In this manner, instead of, or prior to, the punching/burning step, the FETs' Gates can be controlled by an external system.

As shown in FIG. 4C, the voltage divider includes a high-voltage portion that is electrically connected between the AC voltage and the low-voltage portion. In this embodiment, the high voltage portion comprises a high voltage capacitor 71. In alternative aspects, the high-voltage portion can include multiple high-voltage capacitors electrically connected in series with each other.

The low-voltage portion is electrically connected between the high-voltage portion and electrical ground. In this example, the low voltage portion comprises a low-voltage capacitor 111. In alternative aspects the low voltage portion can include multiple low-voltage capacitors, electrically connected in series or in parallel with each other.

In a further alternative embodiment of the present disclosure, FIG. 4D shows an example voltage divider circuit, where the low voltage portion includes a plurality of electro-magnetic relays 97a-97c each connected in series with an associated adjustment capacitor 80a-80c. The voltage divider includes a high-voltage portion that is electrically connected between the AC voltage and the low-voltage portion. In this embodiment, the high voltage portion comprises a high voltage capacitor 71. In alternative aspects, the high-voltage portion can include multiple high-voltage capacitors electrically connected in series with each other.

The low-voltage portion is electrically connected between the high-voltage portion and electrical ground. In this example, the low voltage portion comprises a low-voltage capacitor 111. In alternative aspects the low voltage portion can include multiple low-voltage capacitors, electrically connected in series or in parallel with each other.

The relays 97a-97c can have one or more stable states. For example, if the relays have a single state, a permanent supply of DC energy would be utilized, so that the electrically actuatable elements can be controlled by an external system. In another embodiment, the relays have two stable states (e.g., a bi-stable or latching relay). In this embodiment, only the change of the relay's state would require DC energy on the positive (+) and negative (−) ports. In this manner, a one time signal can be used to change the state between a first state (e.g., off) and a second state (e.g., on) so that the relay would remain in the on state.

In another alternative embodiment, the low voltage portion of the voltage sensor can include a plurality of micro-electro-mechanical or MEMS relay. These relays include electrostatically actuated, micromachined cantilever beam switching elements. This alternative allows for miniaturization of the calibration elements, as four MEMS relays can fit into an SMT IC package (5×4 mm area).

In a further alternative embodiment, instead of an electrically actuatable element, the low voltage portion of the voltage divider can comprise a plurality of magnetically actuated adjustable impedance elements configured to adjust the common overall impedance of the low-voltage portion towards a desired impedance. In this alternative embodiment, the magnetically actuated adjustable impedance elements can comprise a reed switch, actuatable by a permanent magnet or a DC solenoid, connected in series with an adjustment capacitor. If permanent magnets are used to actuate the reed switches, the magnets can be fixed to the finished voltage divider circuit.

In another aspect of the invention, a method of calibrating a voltage sensor is provided. As mentioned above, the adjustment capacitors and the electrically actuatable elements of the voltage sensor are arranged on a printed circuit board. Arrangement on a PCB provides for a straightforward calibration process to be performed to ensure high accuracy of the voltage sensor.

In one example, the voltage sensor can include a voltage divider circuit, such as shown in FIG. 2B, that is mounted on a PCB that is part of a sensor that is implemented in a sensored insulation plug for being inserted into a rear cavity of a medium voltage or high voltage separable connector in a power distribution network.

To perform the calibration procedure, appropriate equipment should be utilized. For example, computers, fixturing and mechanical connections, insulation and safety devices, an HV source/meter, relays, and pulse/current generators can be used.

In one embodiment, the calibration procedure comprises determining which electrically actuatable elements to actuate and performing the actuation.

For an embodiment in which the electrically actuatable elements comprised Zener diodes, selection of the appropriate Zener diodes and their Zener voltages help determine the actual current pulse and compliance voltage necessary to enable a successfully actuation/zap. Bench experimentation showed that a zapping time of 1-5 ms was effective. The following parameters were used during the bench experiments: for a 10V Zener: 30V, ˜1 A @ 1 ms; for a 3V Zener: 10V, ˜0.5 A @ 1 ms.

All cited references, patents, and patent applications in the above application for letters patent are herein incorporated by reference in their entirety in a consistent manner. In the event of inconsistencies or contradictions between portions of the incorporated references and this application, the information in the preceding description shall control. The preceding description, given in order to enable one of ordinary skill in the art to practice the claimed disclosure, is not to be construed as limiting the scope of the disclosure, which is defined by the claims and all equivalents thereto.

1. A voltage sensor for sensing an AC voltage of a HV/MV power conductor, comprising:
a capacitive voltage divider for sensing the AC voltage, wherein the voltage divider comprises
a high-voltage portion comprising one or more high-voltage capacitors, electrically connected in series with each other;
a low-voltage portion comprising one or more low-voltage capacitors, electrically connected with each other between the high-voltage portion and electrical ground;
a signal contact, electrically arranged between the high-voltage portion and the low-voltage portion, for providing a signal voltage, indicative of the AC voltage,
wherein the low-voltage portion further comprises
a plurality of electrically actuated adjustable impedance elements configured to adjust the common overall impedance of the low-voltage portion towards a desired impedance, wherein each electrically actuated adjustable impedance element comprises one or more associated adjustment capacitors and at least one electrically actuatable element,
wherein each electrically actuatable element is associated with and electrically connected to one or more of the adjustment capacitors and wherein each electrically actuatable element is configured to achieve one of a connected state and a disconnected state, wherein
in the connected state, at least one of the associated adjustment capacitors is electrically connected in parallel to the at least one of the one or more low-voltage capacitors, and
in the disconnected state, the associated adjustment capacitor is electrically disconnected from the low-voltage capacitor(s).

2. The voltage sensor of claim 1, wherein each electrically actuatable element comprises first and second Zener diodes connected in series with the adjustment capacitor and arranged in a back-to-back orientation.

3. The voltage sensor of claim 1, wherein each electrically actuatable element comprises a breakable fuse connected in series with the adjustment capacitor.

4. The voltage sensor of claim 1, wherein each electrically actuatable element comprises a breakable fuse and an inductor connected in series with the adjustment capacitor.

5. The voltage sensor of claim 1, wherein each electrically actuatable element comprises at least one field effect transistor connected in series with the adjustment capacitor.

6. The voltage sensor of claim 1, wherein each electrically actuatable element comprises one of an electromagnetic relay connected in series with the adjustment capacitor, a MEMS relay connected in series with the adjustment capacitor, or a solid-state relay connected in series with the adjustment capacitor.

7. Voltage sensor according to claim 1, wherein the plurality of adjustment capacitors comprises at least four adjustment capacitors, or wherein the plurality of adjustment capacitors comprises at least ten adjustment capacitors.

8. Voltage sensor according to claim 1, wherein each adjustment capacitor is associated to one electrically actuatable element.

9. Voltage sensor according to claim 1, wherein each adjustment capacitor has a capacitance of between 0.05% and 50% of the combined capacitance of the one or more low-voltage capacitors.

10. Voltage sensor according to claim 1, wherein the nominal capacitance values of the adjustment capacitors are equally spaced on a logarithmic scale, e.g. represented by an E6 series.

11. Voltage sensor according to claim 1, wherein the overall impedance of the high-voltage portion and the overall impedance of the low-voltage portion of the voltage divider are adapted such that, by bringing one or more of the electrically actuatable elements into their connect state, the voltage divider has, for an AC voltage of between 5 and 25 kV phase-to-ground and a frequency of between 40 and 70 Hertz, a dividing ratio of 3077±0.5% or of 6154±0.5% or of 6769±0.5% or of 000±0.5%.

12. Voltage sensor according to claim 2, wherein at least one electrically actuatable element of the plurality of electrically actuatable elements, after bringing it into its connected state, cannot be brought from its connected state into its disconnect state.

13. Voltage sensor according to claim 3, wherein at least one electrically actuatable element of the plurality of electrically actuatable elements, after bringing it into its disconnected state, cannot be brought from its disconnected state into its connected state.

14. Voltage sensor according to claim 3, wherein one or more selected electrically actuatable elements are irreversibly deactivated.

15. The voltage sensor of claim 5, wherein each at least one field effect transistor comprises an N-channel MOSFET and a P-channel MOSFET connected in series.

16. Voltage sensor according to claim 1, wherein the adjustment capacitors and the electrically actuatable elements are arranged on a printed circuit board.

17. Power network for distributing electrical power in a national grid, the power network comprising an HV/MV power conductor and a voltage sensor according to claim 1, the voltage sensor being electrically connected to the power conductor to sense an AC voltage of the power conductor.

18. A sensored insulation plug for being inserted into a rear cavity of a medium voltage or high voltage separable connector in a power distribution network, comprising the voltage sensor of claim 1.

19. Method of adjusting the common overall impedance of the low-voltage portion of the voltage divider of a voltage sensor according to claim 1 towards a desired impedance, the method comprising the steps of:
determining which electrically actuatable element to actuate, and
bringing at least one of the electrically actuatable elements into the connect state.

20. A voltage sensor for sensing an AC voltage of a HV/MV power conductor, comprising:
a capacitive voltage divider for sensing the AC voltage, wherein the voltage divider comprises
a high-voltage portion comprising one or more high-voltage capacitors, electrically connected in series with each other;
a low-voltage portion comprising one or more low-voltage capacitors, electrically connected with each other between the high-voltage portion and electrical ground;
a signal contact, electrically arranged between the high-voltage portion and the low-voltage portion, for providing a signal voltage, indicative of the AC voltage,
wherein the low-voltage portion further comprises
a plurality of magnetically actuated adjustable impedance elements configured to adjust the common overall impedance of the low-voltage portion towards a desired impedance,
wherein each magnetically actuated adjustable impedance element comprises one or more associated adjustment capacitors and at least one magnetically actuatable element,
wherein each magnetically actuatable element is associated with and electrically connected to one or more of the adjustment capacitors and wherein each magnetically actuatable element is configured to achieve one of a connected state and a disconnected state, wherein
in the connected state, at least one of the associated adjustment capacitors is electrically connected in parallel to at least one of the one or more low-voltage capacitors, and
in the disconnected state, the associated adjustment capacitor is electrically disconnected from the low-voltage capacitor(s).
